(19) United States
(12) Patent Application Publication
(10) Pub. No.: US 2024/0362385 A1
(43) Pub. Date: Oct. 31, 2024

(54) ADJUSTMENTS TO SUPERCONDUCTING ELECTRONIC CIRCUIT DESIGNS USING PASSIVE TRANSMISSION LINE MODELING

(71) Applicant: Synopsys, Inc., Sunnyvale, CA (US)

(72) Inventor: Aaron John BARKER, Broomfield, CO (US)

(21) Appl. No.: 18/141,251

(22) Filed: Apr. 28, 2023

(51) Int. Cl. G06F 30/3308

(52) U.S. Cl. CPC G06F 30/3308

(57) ABSTRACT

The present disclosure describes a system and method for generating and/or adjusting a superconducting electronic circuit design. According to an embodiment, the system includes a memory and a processor communicatively coupled to the memory. The processor determines a slope in a voltage pulse at a transmitter for a passive transmission line of a superconducting electronic circuit design and determines a model for the passive transmission line based on the slope. The processor also simulates the superconducting electronic circuit design using the model and makes an adjustment to the transmitter based on simulating the superconducting electronic circuit design.

### GOVERNMENT LICENSE RIGHTS

This invention was made with United States (U.S.) government support under Contract No. W911NF-17-9-0001 awarded by the Office of the Director of National Intelligence, Intelligence Advanced Research Projects Activity (IARPA), via the U.S. Army Research Office. The U.S. government has certain rights in the invention.

### TECHNICAL FIELD

The present disclosure relates to an electronic design automation (EDA) system. In particular, the present disclosure relates to adjustment of superconducting electronic circuit designs.

### BACKGROUND

Superconducting electronic components or circuits may conduct electricity with zero resistance and expel magnetic flux (Meisner effect) when cooled below a critical temperature (T_{c}). For example, T_{c} for Niobium may be around 9.7 Kelvin (K), and circuits that include Niobium may have a nominal operating temperature of 4.2K, which may be achieved through submersion into liquid helium. It may be challenging, however, to determine how to adjust superconducting electronic components or circuits to improve performance and yield.

### SUMMARY

The present disclosure describes a system and method for generating and/or adjusting a superconducting electronic circuit design. According to an embodiment, the system includes a memory and a processor communicatively coupled to the memory. The processor determines a slope in a voltage pulse at a transmitter for a passive transmission line of a superconducting electronic circuit design and determines a model for the passive transmission line based on the slope. The processor also simulates the superconducting electronic circuit design using the model and makes an adjustment to the transmitter based on simulating the superconducting electronic circuit design.

Determining the model for the passive transmission line may include determining a continuous waveform with a slope that matches the slope in the voltage pulse. Determining the model may be based on a frequency of the continuous waveform.

Determining the model for the passive transmission line may include determining scattering parameters for the passive transmission line.

The model may express how the passive transmission line attenuates at least one of an amplitude, a pulse width, or a shape of the voltage pulse.

Simulating the superconducting electronic circuit design may include sampling an input signal or output signal of the passive transmission line while varying an input to the model representing a length of the passive transmission line. Varying the input may vary a signal reflection from the passive transmission line.

Simulating the superconducting electronic circuit design may include sampling an input signal or output signal of the passive transmission line while varying an input to the model representing a periodicity of a voltage pulse to the passive transmission line.

According to another embodiment, the method includes determining a slope in a voltage pulse at a transmitter for a passive transmission line of a superconducting electronic circuit design and determining a continuous waveform with a slope that matches the slope in the voltage pulse. The method also includes determining a frequency range based on a frequency of the continuous waveform and determining, by a processor, a model for the passive transmission line based on the frequency range.

The method may include simulating the superconducting electronic circuit design using the model and making an adjustment to the transmitter based on simulating the superconducting electronic circuit design.

Determining the slope in the voltage pulse may include determining a maximum derivative of the voltage pulse and a minimum derivative of the voltage pulse. Determining the continuous waveform may include determining a first continuous waveform with a maximum derivative that matches the maximum derivative of the voltage pulse and a second continuous waveform with a minimum derivative that matches the minimum derivative of the voltage pulse. The first continuous waveform may have a first frequency and the second continuous waveform has a second frequency. Determining the continuous waveform may include determining whether the first frequency is greater than the second frequency.

Determining the model for the passive transmission line may include determining scattering parameters for the passive transmission line.

The model may express how the passive transmission line attenuates at least one of an amplitude, pulse width, or shape of the voltage pulse.

Simulating the superconducting electronic circuit design may include sampling an input signal or output signal of the passive transmission line while varying an input to the model representing a length of the passive transmission line. Varying the input may vary a signal reflection from the passive transmission line.

Simulating the superconducting electronic circuit design may include sampling an input signal or output signal of the passive transmission line while varying an input to the model representing a periodicity of a voltage pulse to the passive transmission line.

According to another embodiment, a non-transitory computer readable medium stores instructions that, when executed by a processor, cause the processor to determine a frequency range of a voltage pulse at a transmitter for a passive transmission line of a superconducting electronic circuit design and generate a model for the passive transmission line using the frequency range. The processor also samples a reflected signal from the passive transmission line while varying an input to the model representing a length of the passive transmission line and adjusts the transmitter based on the reflected signal.

Determining the frequency range may include fitting a continuous waveform to the voltage pulse.

The model may include scattering parameters for the passive transmission line.

### BRIEF DESCRIPTION OF THE DRAWINGS

The disclosure will be understood more fully from the detailed description given below and from the accompanying figures of embodiments of the disclosure. The figures are used to provide knowledge and understanding of embodiments of the disclosure and do not limit the scope of the disclosure to these specific embodiments. Furthermore, the figures are not necessarily drawn to scale.

FIG. 1 illustrates an example system for adjusting a superconducting electronic circuit design.

FIGS. 2A, 2B, 2C, and 2D illustrate an example determination of a frequency component of a voltage pulse.

FIG. 3 illustrates the example system of FIG. 1.

FIG. 4 is a flowchart of an example method performed in the system of FIG. 1.

FIG. 5 illustrates the example system of FIG. 1.

FIGS. 6A and 6B illustrate input and output signals from simulating a superconducting electronic circuit design.

FIGS. 7A and 7B illustrate input and output signals after adjusting a superconducting electronic circuit design.

FIG. 8 is a flowchart of an example method performed in the system of FIG. 1.

FIG. 9 depicts a flowchart of various processes used during the design and manufacture of an integrated circuit in accordance with some embodiments of the present disclosure.

FIG. 10 depicts a diagram of an example computer system in which embodiments of the present disclosure may operate.

### DETAILED DESCRIPTION

Aspects of the present disclosure relate to adjustments to superconducting electronic circuit designs using passive transmission line modeling. When designing superconducting electronic circuit designs, it may be possible to integrate circuits or connect circuit components using passive transmission lines. It may be challenging, however, to model or characterize the behavior of the passive transmission lines, and as a result, analyze the effect of the passive transmission lines on the behavior or operation of the superconducting electronic circuit designs. Thus, it may also be challenging to determine how to adjust the passive transmission line, the transmitter of the passive transmission line, or the receiver of the passive transmission line to improve performance.

The present disclosure describes a system and method for adjusting a superconducting electronic circuit design. The system models a passive transmission line of the superconducting electronic circuit design by analyzing how the passive transmission line attenuates a signal passing through the passive transmission line. For example, the system may determine a frequency range for the frequency components present in the signal. The system may then generate a model that characterizes the passive transmission line by sampling over the frequency range. The model may include parameters for the passive transmission line (e.g., scattering parameters, impedance, propagation velocity, etc.) that may be used to simulate the passive transmission line. After generating the model, the system may use the model to simulate the superconducting electronic circuit design (e.g., while varying a length of the passive transmission or the pulse periodicity of an input pulse to the passive transmission line). Using these simulations, the system may determine and make an adjustment to the superconducting electronic circuit design that improves the performance of the superconducting electronic circuit design. For example, the system may adjust the values or sizes of components of the superconducting electronic circuit design (e.g., values and sizes of components in the transmitter or receiver of the passive transmission line).

In certain embodiments, the system provides several technical advantages. For example, the system may produce models that more accurately characterize the behavior of passive transmission lines. As a result, the system may perform a more accurate simulation of the superconducting electronic circuit design, which may result in the adjustment to the superconducting electronic circuit design yielding a better improvement to the performance of the superconducting electronic circuit design.

Although the system is described as applying a design technique to superconducting electronic circuit designs, it is understood that the system may apply the design technique to any suitable electronic circuit design. For example, the system may be used to update a complementary metal-oxide semiconductor (CMOS) device.

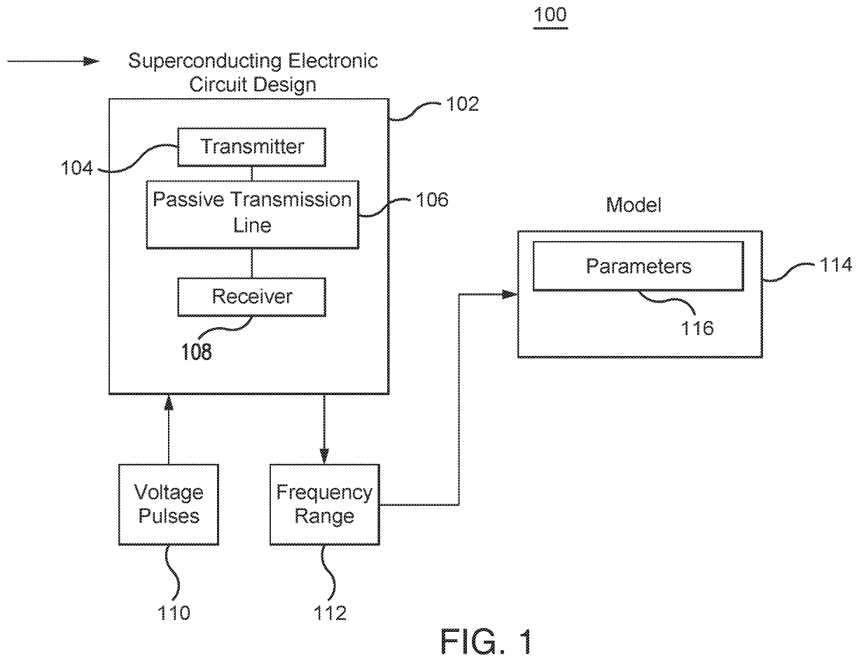

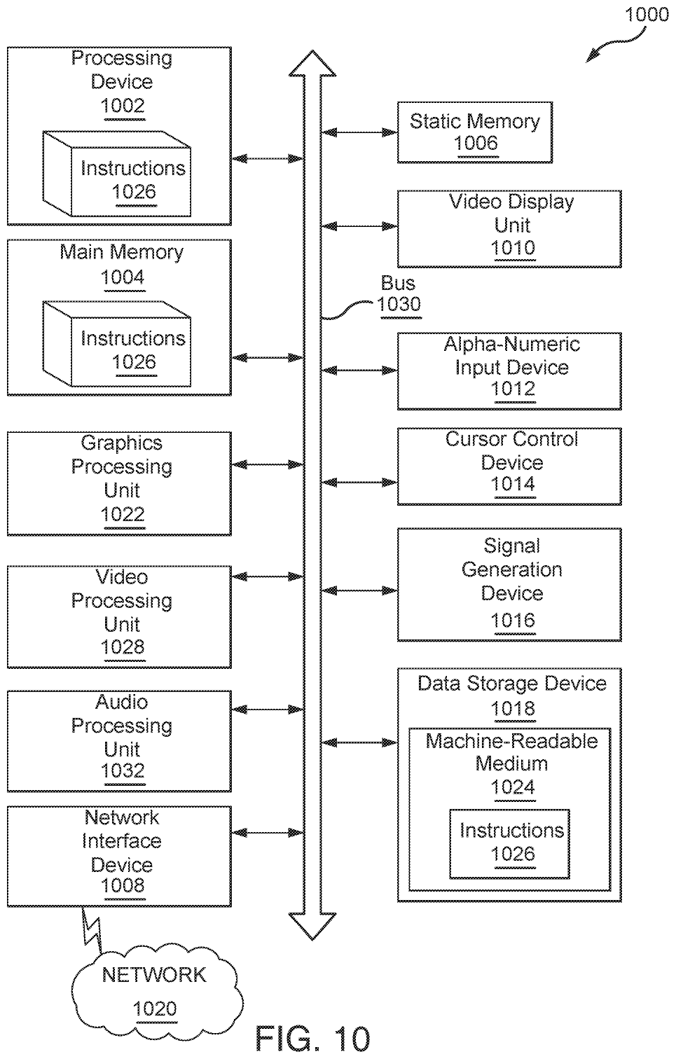

FIG. 1 illustrates an example system 100 for adjusting a superconducting electronic circuit design. Generally, the system 100 may be a computer system (e.g., the computer system 100 shown in FIG. 10). In the example of FIG. 1, the system 100 generates a model for a passive transmission line in the superconducting electronic circuit design.

The system 100 receives a superconducting electronic circuit design 102 from a user or designer. The superconducting electronic circuit design 102 may include a superconducting electronic circuit or a superconducting electronic circuit component. The superconducting electronic circuit or the superconducting circuit component may include a superconducting material (e.g., niobium) that conducts electricity with zero resistance. The superconducting electronic circuit design 102 may be part of a quantum device or a quantum computer. For example, the superconducting electronic circuit design 102 may include Josephson junctions, adiabatic quantum flux parametron (AQFP) logic, rapid single flux quantum (RSFQ) logic, energy-efficient rapid single flux quantum (ERSFQ) logic, or reciprocal quantum logic (RQL). In the example of FIG. 1, the superconducting electronic circuit design 102 includes a transmitter 104, a passive transmission line 106, and a receiver 108. The transmitter 104, passive transmission line 106, and receiver 108 may integrate or connect other circuit components of the superconducting electronic circuit design 102.

Generally, the transmitter 104, passive transmission line 106, and receiver 108 carry signals (e.g., voltage or current signals) as transverse electromagnetic (TEM) waves from a portion of the superconducting electronic circuit design 102 to another portion of the superconducting electronic circuit design 102. The transmitter 104 may transmit the voltage signal (e.g., single flux quantum (SFQ) pulse) over the passive transmission line 106. The passive transmission line 106 may carry or propagate the voltage signal to the receiver 108. The receiver 108 receives the voltage signal (e.g., as a TEM wave) and reconstitutes it back into an SFQ pulse. The receiver 108 then directs the signal onto other portions of the superconducting electronic circuit design 102.

The passive transmission line 106 may affect or alter the voltage signal as the passive transmission line 106 carries or propagates the voltage signal. In some instances, the effects of the passive transmission line 106 may be minimal and ignored. For example, if the system 100 determines that the ratio of the length of the passive transmission line 106 to the wavelength present in the voltage signal falls below a threshold (e.g., 0.01), then the system 100 may not necessarily need to perform the modeling or simulation technique for the passive transmission line 106 described herein (e.g., a simple inductor-capacitor (LC) network may suffice in place of the passive transmission line model).

In many instances, however, the transmission line effects of the passive transmission line 106 (e.g., inductive phase shift, reflected signals, skin effect, dielectric loss, and other forms of scattering and loss) may not be neglected. For example, the system 100 may not ignore these effects when the ratio of the length of the passive transmission line 106 to the wavelength present in the voltage signal exceeds a threshold (e.g., 0.01). In these instances, the system 100 may model or characterize the passive transmission line 106 so that the effects introduced by the passive transmission line 106 may be considered when the system 100 analyzes or characterizes the behavior of the superconducting electronic circuit design 102.

The system 100 may model the passive transmission line 106 to characterize the behavior of the transmission line 106 or the effects introduced by the passive transmission line 106. The system 100 may begin by analyzing one or more voltage pulses 110 at the transmitter 104. The voltage pulses 110 may be transmitted by the transmitter 104 to the transmission line 106 at a certain frequency or with a certain periodicity (e.g., repeatedly transmitted by the transmitter 104 at a particular frequency or with a certain periodicity). The voltage pulses 110 may include one or more frequency components that are carried or propagated by the passive transmission line 106. The system 100 may analyze the voltage pulses 110 to determine a maximum frequency component of the voltage pulses 110.

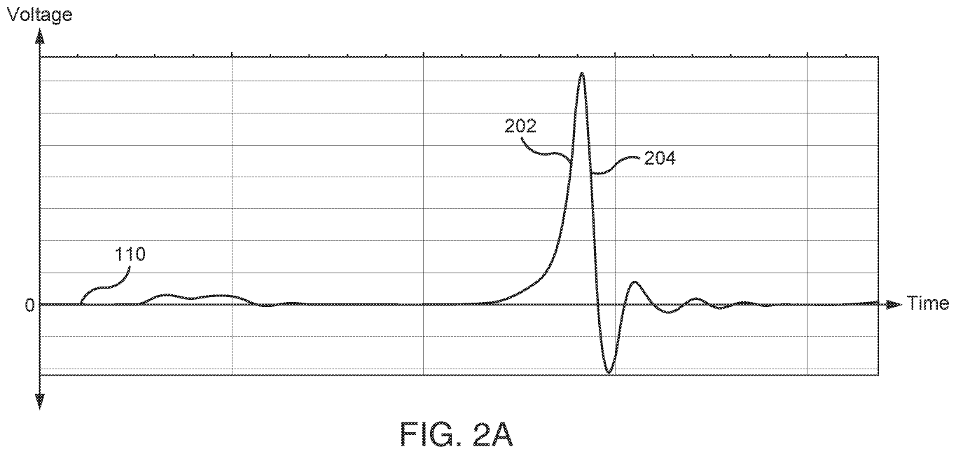

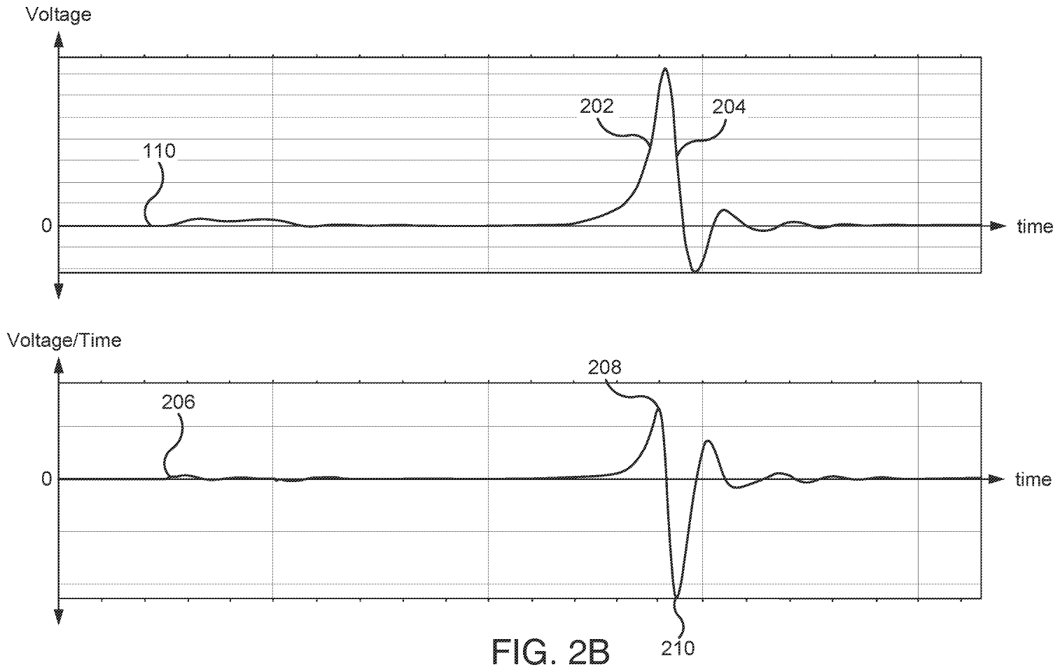

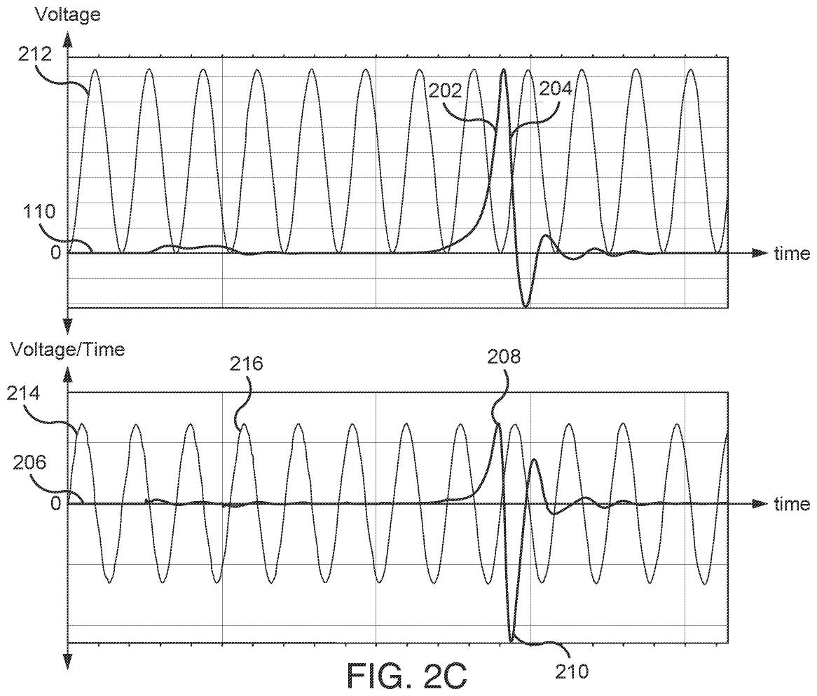

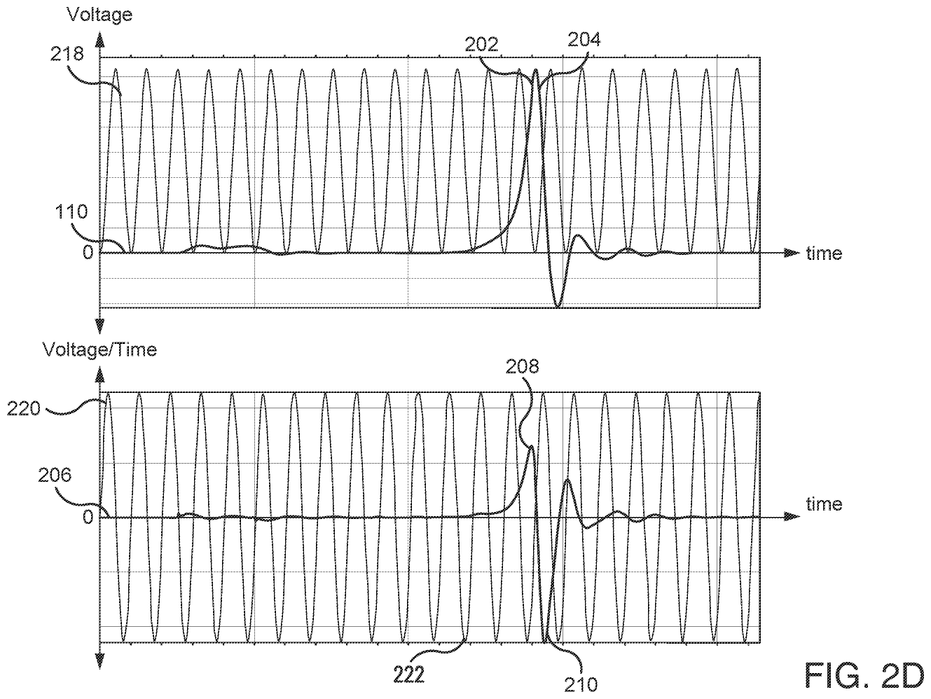

FIGS. 2A, 2B, 2C, and 2D illustrate an example of the system 100 determining a maximum frequency component of a voltage pulse 110. As seen in FIG. 2A, the voltage pulse 110 may be a signal that includes a rising edge 202 and a falling edge 204. The system 100 may first analyze the continuous derivative of the voltage pulse 110 to identify the point where the derivative is maximized so as to identify the rising edge 202 where the slope is greatest (e.g., identify the point where the slope is positive and has the greatest magnitude). The system 100 may then analyze the continuous derivative of the signal to identify the point where the derivative is minimized as to identify the falling edge 204 where the slope is greatest (e.g., identify the point where the slope is negative and has the greatest magnitude).

FIG. 2B illustrates the voltage pulse 110 and a curve 206 representing the derivative of the voltage pulse 110. Thus, the curve 206 indicates the slope along the voltage pulse 110. As seen in FIG. 2B, the maximum derivative occurs at a point 208 on the curve 206. Additionally, the minimum derivative occurs at a point 210 on the curve 206. The point 208 aligns with a point on the rising edge 202 of the voltage pulse 110. This point on the rising edge 202 is where the positive slope with the greatest magnitude occurs. The point 210 aligns with a point on the falling edge 204 of the voltage pulse 110. This point on the falling edge 204 is where the negative slope with the greatest magnitude occurs.

The system 100 may then determine and fit a continuous waveform (e.g., sine waves or cosine waves) with slopes that match or substantially equal the steepest slopes on the points on the rising edge 202 and the falling edge 204. This may be accomplished using a numerical optimizer (e.g., using a bisection method). FIGS. 2C and 2D illustrate the fitting of sine waves to the voltage pulse 110. As seen in FIG. 2C, the voltage pulse 110 is fitted with a sine wave 212. FIG. 2C also illustrates a curve 214 representing the derivative of the sine wave 212. Thus, the curve 214 shows the slope along the sine wave 212. The point 216 is the maximum of the curve 214, and the point 216 has the same magnitude (voltage/time value) as the point 208 on the curve 206. Thus, the sine wave 212 has a maximum positive slope that matches the maximum positive slope of the voltage pulse 110. The system 100 may then determine a frequency of the sine wave 212.

As seen in FIG. 2D, the voltage pulse 110 is fitted with a sine wave 218. FIG. 2D also illustrates a curve 220 representing the derivative of the sine wave 218. Thus, the curve 220 shows the slope along the sine wave 218. The point 222 is the minimum of the curve 220, and the point 222 has the same magnitude (voltage/time value) as the point 210 on the curve 206. Thus, the sine wave 218 has a minimum negative slope (e.g., a negative slope with the greatest magnitude) that matches the minimum negative slope of the voltage pulse 110. The system 100 may then determine a frequency of the sine wave 218.

As seen in FIGS. 2C and 2D, the sine wave 218 has a higher frequency than the sine wave 212. As a result, the system 100 considers the frequency of the sine wave 218 as the maximum frequency component of the voltage pulse 110. This maximum frequency component may then be used to set the upper bound for a frequency range.

Returning to FIG. 1, the system 100 uses the frequency range 112 to generate a model 114 for the passive transmission line 106. The lower bound for the frequency range 112 may be a frequency at which the voltage pulses 110 are communicated by the transmitter 104 to the passive transmission line 106 (e.g., an inverse of the periodicity of the voltage pulses 110). The upper bound of the frequency range 112 may be the maximum frequency component of the voltage pulses 110.

Generally, the system 100 may sample the effect of the passive transmission line 106 on voltage signals of different frequencies to generate the model 114. The system 100 may simulate voltage signals (e.g., from zero Hertz (Hz) to the second or third harmonic) being sent through the passive transmission line 106 and analyze the output from the passive transmission line 106. The system 100 may generate ten samples per frequency decade, with each frequency decade spanning an order of magnitude of the frequency. For example, a frequency range from zero Hz to ten Hz may be one decade, and a frequency range from ten Hz to 100 Hz may be another decade.

The system 100 may use denser sampling when the frequency of the voltage signal is within the frequency range 112. For example, the system 100 may supplement the samples within the frequency range 112 so that denser sampling is performed in the frequency range 112. The denser sampling may improve the accuracy of the model 114 for the passive transmission line 106 by providing additional data points for the frequency range 112 of the voltage pulse 110.

These samples may indicate how the passive transmission line 106 affects or attenuates amplitude, pulse width, and/or shape of the voltage signals of different frequencies. The model 114 may include parameters 116 that express or describe how the passive transmission line 106 affects or attenuates these characteristics of the voltage signals. For example, the parameters 116 may include scattering parameters of the passive transmission line 106, which describe the linear characteristics of the passive transmission line 106 and may be used to derive gain, loss, impedance, phase group delay, etc. Additionally, the parameters 116 may express or describe how the passive transmission line 106 affects or attenuates characteristics of any reflections of the voltage signals in or through the passive transmission line 106.

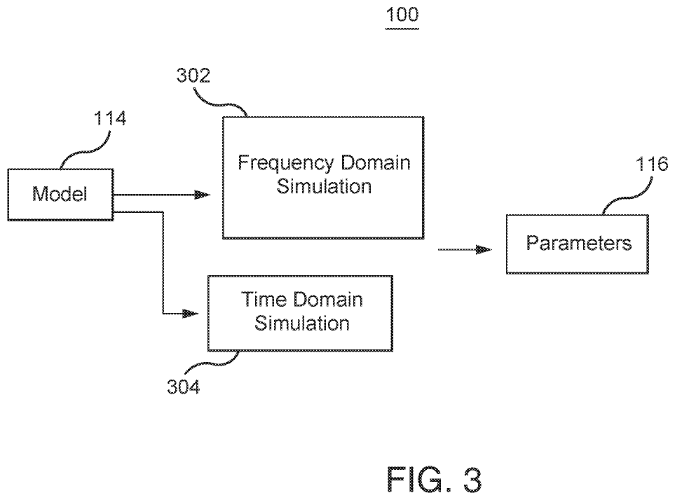

The system 100 may perform any suitable type of simulation of the passive transmission line 106 to determine the parameters 116 for the model 114. FIG. 3 illustrates the example system 100 of FIG. 1 simulating the passive transmission line 106. As seen in FIG. 3, the system 100 may perform frequency domain simulation 302 and time domain simulation 304 to generate some of the parameters 116 for the model 114. For example, during frequency domain simulation 302, the system 100 may perform a network analysis upon the passive transmission line 106 to extract one or more characteristic parameters (e.g., characteristic impedance of the passive transmission line 106). During time domain simulation 304, the system 100 may simulate a sine wave stimulus through the passive transmission line 106. The system 100 may then characterize the delay, the delay per unit length, or the propagation velocity while sweeping the length of the passive transmission line 106.

After performing the frequency domain simulation 302 and the time domain simulation 304, the system 100 may produce the parameters 116 to add to the model 114. For example, the parameters 116 may include the characteristic impedance and the propagation velocity determined using the frequency domain simulation 302 and the time domain simulation 304.

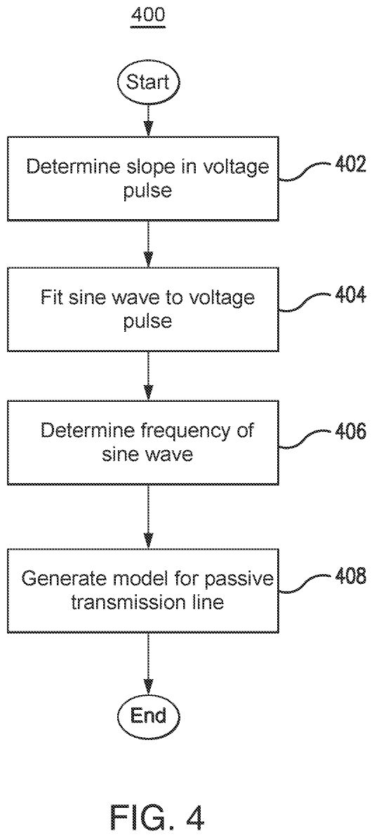

FIG. 4 is a flowchart of an example method 400 performed in the system 100 of FIG. 1. In particular embodiments, a computer system (e.g., the computer system 1000 shown in FIG. 10) may perform the method 400. By performing the method 400, the computer system generates a model 114 that describes or expresses the behavior of the passive transmission line 106 of the superconducting electronic circuit design 102.

At 402, the computer system determines a slope in a voltage pulse 110. The voltage pulse 110 may be directed by the transmitter 104 to the passive transmission line 106. The computer system may analyze the voltage pulse 110 to determine the steepest slope in a rising edge 202 of the voltage pulse 110 (e.g., the positive slope with the greatest magnitude) and the steepest slope in a falling edge 204 of the voltage pulse 110 (e.g., the negative slope with the greatest magnitude).

At 404, the computer system may fit a sine wave to the voltage pulse 110. The sine wave may have a positive slope with a greatest magnitude or a negative slope with a greatest magnitude that matches the steepest slope in the rising edge 202 or the steepest slope in the falling edge 204 of the voltage pulse 110, respectively. At 406, the computer system determines a frequency of the sine wave. This frequency may bound the frequency range 112 and may be the maximum frequency component present in the voltage pulse 110.

At 408, the computer system generates the model 114 for the passive transmission line 106. The computer system may communicate voltage signals of various frequencies through the passive transmission line 106 and capture the output of the passive transmission line 106. The computer system may communicate ten samples per decade from zero Hz to the second or third harmonic. The computer system may communicate additional voltage signals within the frequency range 112 through the passive transmission line 106 to generate additional samples for the frequency range 112.

For each sample, the computer system may analyze how the passive transmission line affects or attenuates the amplitude, pulse width, and/or shape of the voltage signal communicated through the passive transmission line 106. Through this analysis, the computer system may generate or determine the parameters 116 for the passive transmission line 106, which may include the scattering parameters of the passive transmission line 106. The parameters 116 may express or describe the effects of the passive transmission line 106 on the voltage signals communicated through the passive transmission line 106. The computer system may add the parameters 116 to the model 114.

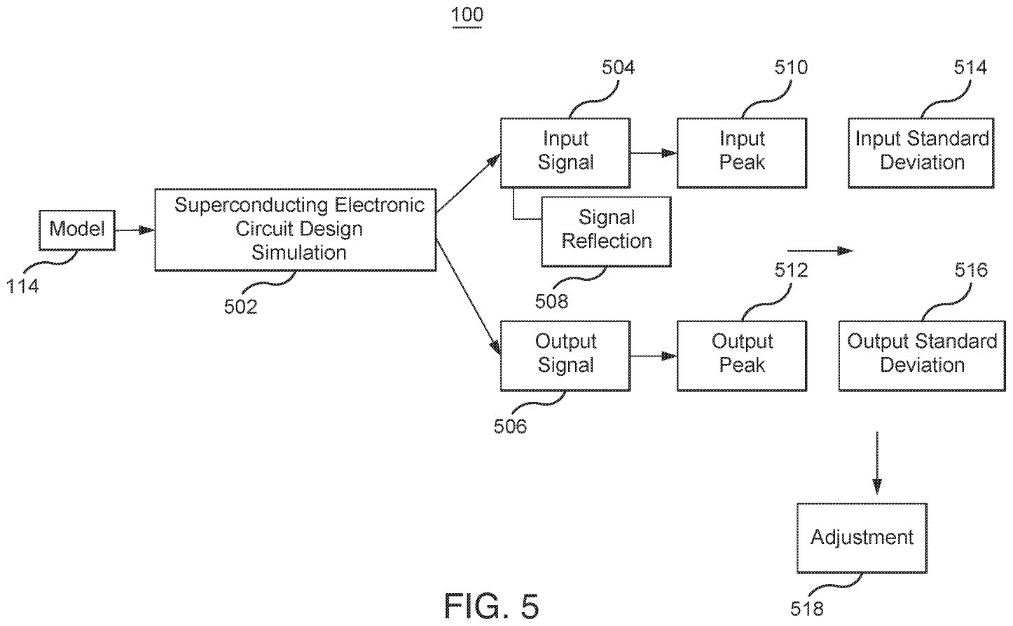

After generating the model 114 that expresses or describes the behavior of the passive transmission line 106, the system 100 may use the model 114 when simulating the superconducting electronic circuit design 102. FIG. 5 illustrates the example system 100 of FIG. 1 simulating the superconducting electronic circuit design 102. Generally, the system 100 may simulate the superconducting electronic circuit design 102 to determine one or more adjustments that may improve the operation of the superconducting electronic circuit design 102.

The system 100 may perform a superconducting electronic circuit design simulation 502. The system 100 may use the model 114 when performing the superconducting electronic circuit design simulation 502. During the superconducting electronic circuit design simulation 502, the system 100 may simulate the behavior of various components of the superconducting electronic circuit design 102. When the system 100 simulates the behavior of the transmitter 104, the passive transmission line 106, or the receiver 108, the system 100 may use the model 114 to simulate the transmitter 104, the passive transmission line 106, or the receiver 108.

During these simulations, the system 100 may communicate a voltage signal through the transmitter 104, the passive transmission line 106, and the receiver 108. The system 100 may then analyze the peak voltages in the voltage signal at the input and the output of the transmitter 104, passive transmission line 106, or receiver 108. During each simulation, the system 100 may vary the length of the passive transmission line 106 and/or the periodicity of the pulses in the voltage signal (e.g., by varying puts to the model 114 that represent the length of the passive transmission line 106 or the periodicity of the pulses). The system 100 may then analyze the peak voltages in the inputs and outputs to determine an adjustment to be made to the superconducting electronic circuit design 102.

In the example of FIG. 5, the system 100 communicates an input signal 504 to the passive transmission line 106. The input signal 504 may be a voltage signal that includes voltage pulses. The voltage pulses may be communicated to the passive transmission line 106 with a certain periodicity. The system 100 may use the input signal 504 as an input to the model 114. The model 114 may then produce the output signal 506 based on the information in the model 114 that describes the effect of the passive transmission line 106 on the input signal 504. The information in the model 114 may also describe how the passive transmission line 106 reflects the input signal 504. Thus, the model 114 may also produce a signal reflection at 508 that describes the reflected signal from the passive transmission line 106. Sending the voltage signal through the passive transmission line 106 may also produce the output signal 506.

The system 100 may determine peak voltages in the input signal 504, the signal reflection 508, and the output signal 506 to determine peak voltages in these signals. The system 100 may determine an input peak 510 for the input signal 504 and the signal reflection 508. In some embodiments, the signal reflection 508 may coincide with the input signal 504 and cause the peak voltage of a voltage pulse in the input signal 504 to further increase, which may result in the input peak 510. The system 100 may analyze the output signal 506 to determine the output peak 512. The output peak 512 may be a peak voltage of a voltage pulse in the output signal 506.

The system 100 may perform several iterations of the simulation while varying the length of the passive transmission line 106 or a periodicity of the voltage pulses in the input signal 504. These iterations may produce multiple signal reflections 508 and output signals 506. The system 100 may determine multiple input peaks 510 and output peaks 512 for these iterations. The system 100 may analyze the multiple input peaks 510 and output peaks 512 to determine the standard deviations of the input peaks 510 and output peaks 512. As seen in FIG. 5, the system 100 may determine an input standard deviation 514 for the input peaks 510 and an output standard deviation 516 for the output peaks 512 relative to the perturbations in length and or periodicity. In some embodiments, the number of iterations of the simulation may be a predefined or selected value. In certain embodiments, the number of iterations may be set based on a range for the length of the passive transmission line 106 or the periodicity of the voltage pulse to be sampled.

The system 100 may determine an adjustment 518 to the superconducting electronic circuit design 102. The adjustment 518 may be made to any component in the superconducting electronic circuit design 102. For example, the adjustment 518 may be an adjustment to the value or size of any component in the superconducting electronic circuit design 102. The adjustment to 518 may be an adjustment to the value or size of a component of the transmitter 104, the passive transmission line 106, or the receiver 108. For example, the adjustment 518 may be an adjustment to the value or size of an inductor, resistor, capacitor, or Josephson junction of the transmitter 104, passive transmission line 106, or receiver 108. In some embodiments, the candidate component or components may be selected by a user. For example, the user may select the transmitter 104, the passive transmission line 106, or the receiver 108, and the system 100 may determine an adjustment 518 for any component of the transmitter 104, the passive transmission line 106, or the receiver 108.

The system 100 may make the adjustment 518 to the superconducting electronic circuit design 102 if the adjustment 118 reduces the input standard deviation 514 and/or the output standard deviation 516. In some embodiments, the system 100 determines the adjustment 518 that minimizes the input standard deviation 514 and the output standard deviation 516 (e.g., select the adjustment 518 from a set of adjustments because the adjustment 518 most reduces the input standard deviation 514 and the output standard deviation 516 out of the set of adjustments). The system 100 may make the adjustment 518 and re-simulate the superconducting electronic circuit design 102 with the adjustment 518 to see if the adjustment 518 reduces the input standard deviation 514 and/or the output standard deviation 516. The system 100 may continue determining and making adjustments 518 to the superconducting electronic circuit design 102 if these further adjustments 518 further reduce the input standard deviation 514 and/or the output standard deviation 516. In this manner, the system 100 continues adjusting the superconducting electronic circuit design 102 to further improve the operation of the superconducting electronic circuit design 102.

Specifically, by making adjustments 518 that reduce the input standard deviation 514 and/or the output standard deviation 516, the system 100 may make adjustments 518 that reduce the signal reflections 508 from the passive transmission line 106 and that reduce signal degradation in the output signal 506. As a result, the adjustments 518 may improve the performance of the passive transmission line 106, in certain embodiments.

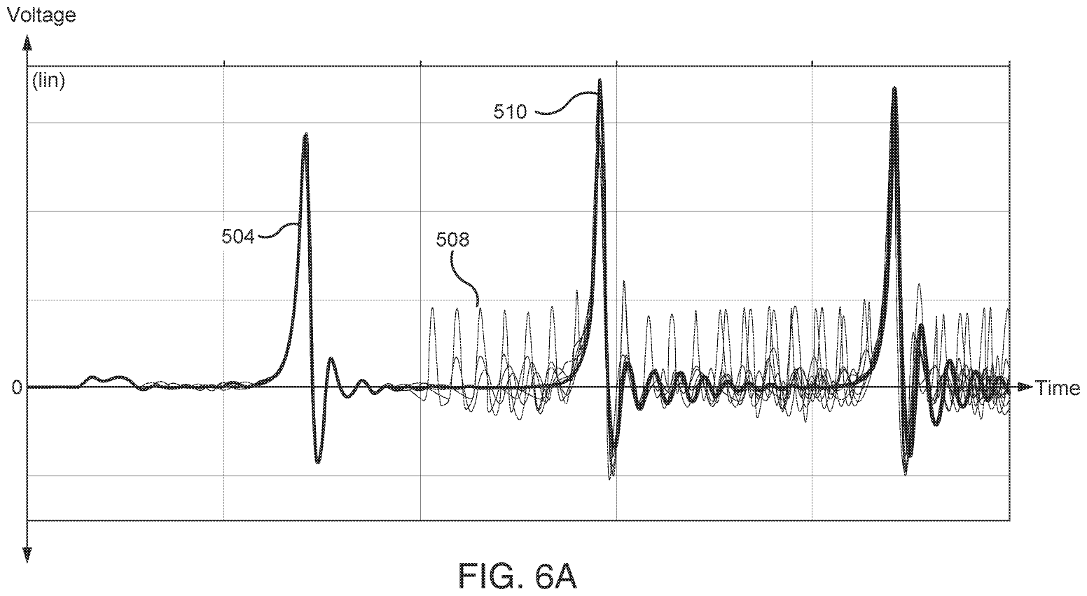

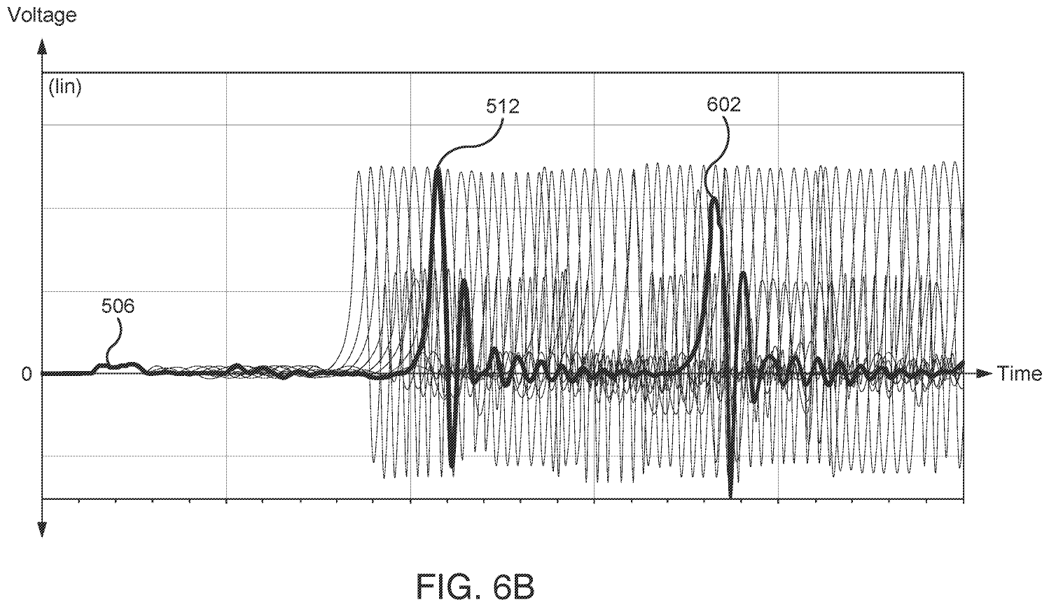

FIG. 6A illustrates an example input signal 504 during iterations of simulations of the passive transmission line 106. As seen in FIG. 6A, the input signal 504 includes three voltage pulses. Additionally, the passive transmission line 106 may reflect the input signal 504 to produce various signal reflections 508. The signal reflections 508 shown in FIG. 6A may be produced for different iterations of the simulations of the passive transmission line 106. Each iteration may vary the length of the passive transmission line 106, which produces the different signal reflections 508. Thus, the simulations may send the same voltage signal 504 through the passive transmission line 106 while varying the length of the passive transmission line 106. The different lengths of the passive transmission line 106 may cause different signal reflections 508 to be produced.

Some of the signal reflections 508 may coincide or align with one or more of the voltage pulses in the voltage signal 504. As seen in FIG. 6A, some of the signal reflections 508 may align with a voltage pulse in the voltage signal 504, which causes an input peak 510 on the voltage pulse. The input peak 510 may be higher than the peaks of the other voltage pulses in the voltage signal 504.

FIG. 6B illustrates example output signals 506 from the passive transmission line 106. Specifically, the output signals 506 may be produced by the various lengths of the passive transmission line 106. The output signals 506 have an output peak 512. Additionally, as seen in FIG. 6B, the output signals 506 exhibit signal degradation 602 around a peak of the output signals 506. This signal degradation may be caused by the signal reflections 508 coinciding or aligning with the voltage pulse on the input signal 504, as seen in FIG. 6A. The system 100 may determine an adjustment 518 that reduces the signal reflections 508 and the signal degradation 602.

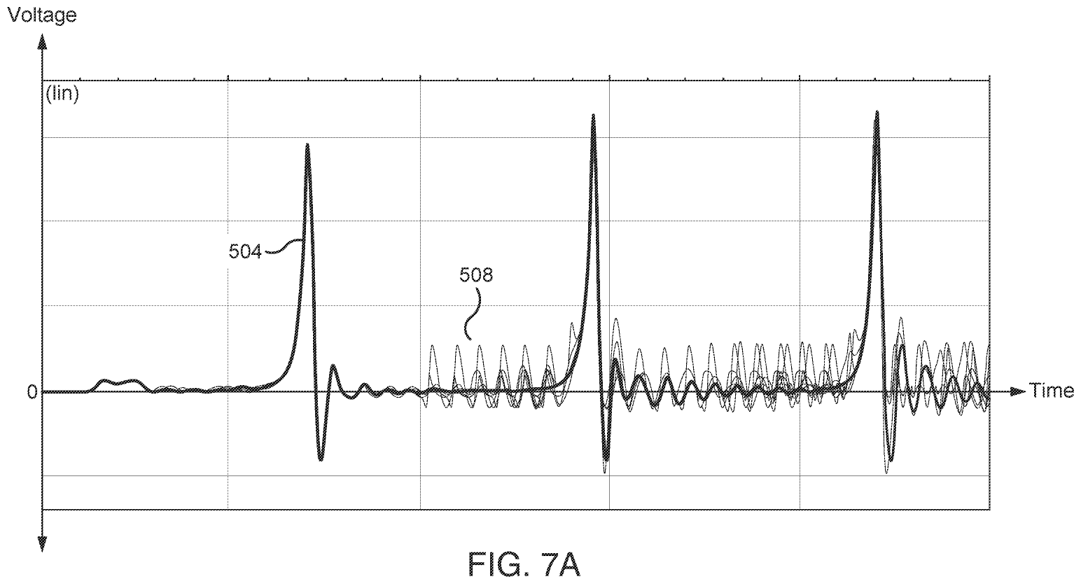

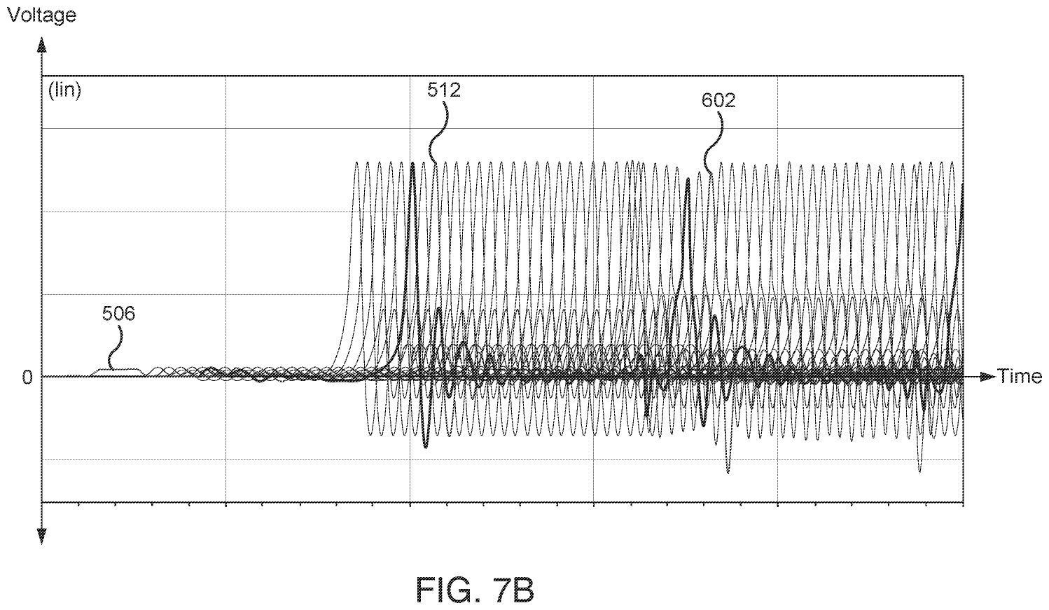

FIG. 7A illustrates an example input signal 504 to the passive transmission line 106 after the system 100 has made the adjustment 518. As seen in FIG. 7A, the simulations of the passive transmission line 106 while varying the length of the passive transmission line 106 may still produce signal reflections 508. However, the amplitudes of the signal reflections 508 have been reduced when compared with the signal reflections 508 shown in FIG. 6A. As a result, even though the signal reflections 508 coincide or align with voltage pulses in the voltage signal 504, the reduced amplitude of the signal reflections 508 causes the voltage peak to be lower than the voltage peak shown in FIG. 6A. As a result, the standard deviations 514 of these input peaks 510 in the voltage signal 504 may be reduced after making the adjustment 518.

FIG. 7B illustrates example output signals 506 of the simulations of the passive transmission line 106. As seen in FIG. 7B, the output signals 506 may continue to have the output peaks 512. Additionally, the signal degradation 602 in the output signals 506 have been reduced. Specifically, the peaks of the output signal 506 near or around the signal degradation 602 are higher than the peaks shown in FIG. 6B. As a result, the standard deviation 516 of the output peaks 512 of the output signals 506 is reduced after making the adjustment 518. Thus, the adjustment 518 improves the operation of the passive transmission line 106 (e.g., reduces signal reflections 508 and signal degradation at the output).

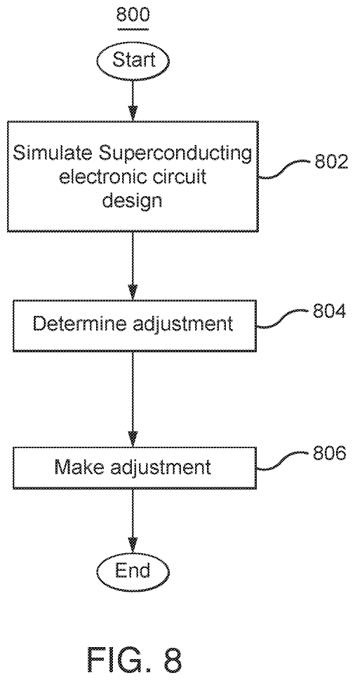

FIG. 8 is a flowchart of an example method 800 performed in the system 100 of FIG. 1. In particular embodiments, a computer system (e.g., the computer system 1000 of FIG. 10) performs the method 800. By performing the method 800, the computer system may determine and make an adjustment 518 to the superconducting electronic circuit design 102 that improves the operation of the superconducting electronic circuit design 102.

At 802, the computer system simulates the superconducting electronic circuit design 102. Specifically, the computer system may simulate the behavior of various components of the superconducting electronic circuit design 102. For example, the computer system may simulate the behavior of the transmitter 104, the passive transmission line 106, and/or the receiver 108 of the superconducting electronic circuit design 102. The computer system may use the model 114 to simulate the behavior of the transmitter 104, the passive transmission line 106, or the receiver 108. The computer system may perform several iterations of the simulation while varying the length of the passive transmission line 106 or while varying a periodicity of a voltage pulses in the input signal 504 to the passive transmission line 106. The passive transmission line 106 may reflect the input signal 504 to produce a signal reflection 508 for each simulation. Additionally, the passive transmission line 106 may produce an output signal 506 for each simulation.

The computer system may determine the input peaks 510 and the output peaks 512 in the input signal 504 and the output signals 506 across the iterations of the simulation. The computer system may then determine the input standard deviation 514 of the input peaks 510 and the output standard deviation 516 of the output peaks 512. The input peaks 510 may vary and have a standard deviation because the signal reflections 508 may align or coincide some of the input peaks 510, causing an increase in these input peaks 510. The output peaks 512 may vary and have a standard deviation (e.g., experience signal degradation) because of the increases in the input peaks 510 caused by the signal reflections 508.

At 804, the computer system determines the adjustment 518 to be made to a component of the superconducting electronic circuit design 102. For example, the adjustment 518 may adjust the value or size of a component of the transmitter 104, the passive transmission line 106, or the receiver 108 (e.g., an inductor, a resistor, a capacitor, or a Josephson junction). The computer system may then simulate the behavior of the superconducting electronic circuit design 102 after making the adjustment 518. For example, the computer system may simulate the behavior of the passive transmission line 106 after making the adjustment 518. The computer system may determine whether making the adjustment 518 reduces the input standard deviation 514 and/or the output standard deviation 516. If the adjustment 518 reduces the input standard deviation 514 or the output standard deviation 516, the computer system may make the adjustment to 518 to the superconducting electronic circuit design 102 at 806. The computer system may perform several iterations of the method 800 to make multiple adjustments 518 to the superconducting electronic circuit design 102. In this manner, the computer system further improves or optimizes the performance of the superconducting electronic circuit design 102, in certain embodiments.

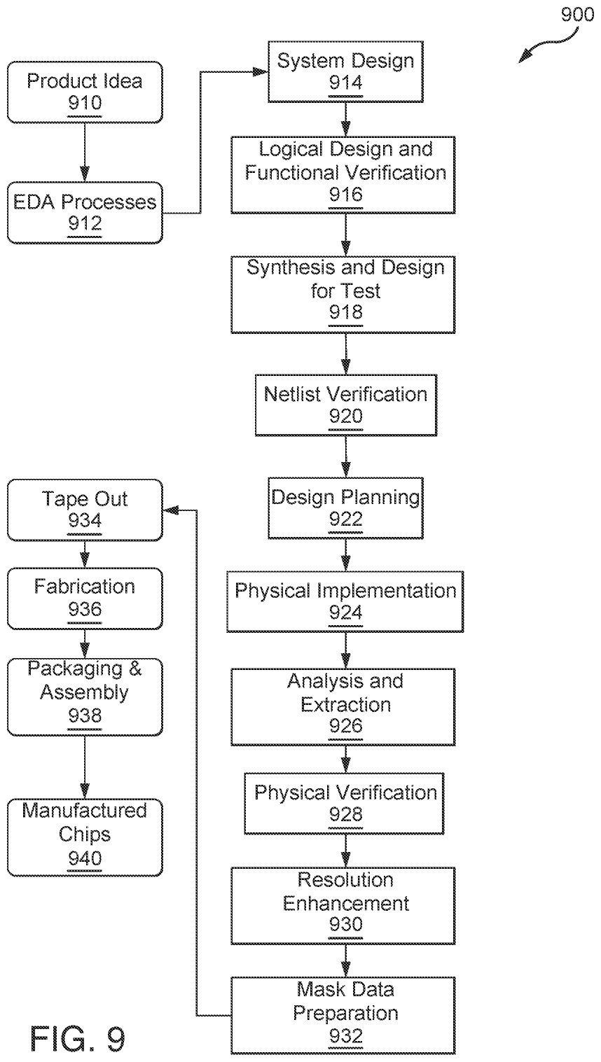

FIG. 9 illustrates an example set of processes 900 used during the design, verification, and fabrication of an article of manufacture such as an integrated circuit to transform and verify design data and instructions that represent the integrated circuit. Each of these processes can be structured and enabled as multiple modules or operations. The term ‘EDA’ signifies the term ‘Electronic Design Automation.’ These processes start with the creation of a product idea 910 with information supplied by a designer, information which is transformed to create an article of manufacture that uses a set of EDA processes 912. When the design is finalized, the design is taped-out 934, which is when artwork (e.g., geometric patterns) for the integrated circuit is sent to a fabrication facility to manufacture the mask set, which is then used to manufacture the integrated circuit. After tape-out, a semiconductor die is fabricated 936 and packaging and assembly processes 938 are performed to produce the finished integrated circuit 940.

Specifications for a circuit or electronic structure may range from low-level transistor material layouts to high-level description languages. A high-level of representation may be used to design circuits and systems, using a hardware description language (‘HDL’) such as VHDL, Verilog, System Verilog, SystemC, MyHDL or OpenVera. The HDL description can be transformed to a logic-level register transfer level (‘RTL’) description, a gate-level description, a layout-level description, or a mask-level description. Each lower representation level that is a more detailed description adds more useful detail into the design description, for example, more details for the modules that include the description. The lower levels of representation that are more detailed descriptions can be generated by a computer, derived from a design library, or created by another design automation process. An example of a specification language at a lower level of representation language for specifying more detailed descriptions is SPICE, which is used for detailed descriptions of circuits with many analog components. Descriptions at each level of representation are enabled for use by the corresponding systems of that layer (e.g., a formal verification system). A design process may use a sequence depicted in FIG. 9. The processes described by be enabled by EDA products (or EDA systems).

During system design 914, functionality of an integrated circuit to be manufactured is specified. The design may be optimized for desired characteristics such as power consumption, performance, area (physical and/or lines of code), and reduction of costs, etc. Partitioning of the design into different types of modules or components can occur at this stage.

During logic design and functional verification 916, modules or components in the circuit are specified in one or more description languages and the specification is checked for functional accuracy. For example, the components of the circuit may be verified to generate outputs that match the requirements of the specification of the circuit or system being designed. Functional verification may use simulators and other programs such as testbench generators, static HDL checkers, and formal verifiers. In some embodiments, special systems of components referred to as ‘emulators’ or ‘prototyping systems’ are used to speed up the functional verification.

During synthesis and design for test 918, HDL code is transformed to a netlist. In some embodiments, a netlist may be a graph structure where edges of the graph structure represent components of a circuit and where the nodes of the graph structure represent how the components are interconnected. Both the HDL code and the netlist are hierarchical articles of manufacture that can be used by an EDA product to verify that the integrated circuit, when manufactured, performs according to the specified design. The netlist can be optimized for a target semiconductor manufacturing technology. Additionally, the finished integrated circuit may be tested to verify that the integrated circuit satisfies the requirements of the specification.

During netlist verification 920, the netlist is checked for compliance with timing constraints and for correspondence with the HDL code. During design planning 922, an overall floor plan for the integrated circuit is constructed and analyzed for timing and top-level routing.

During layout or physical implementation 924, physical placement (positioning of circuit components such as transistors or capacitors) and routing (connection of the circuit components by multiple conductors) occurs, and the selection of cells from a library to enable specific logic functions can be performed. As used herein, the term ‘cell’ may specify a set of transistors, other components, and interconnections that provides a Boolean logic function (e.g., AND, OR, NOT, XOR) or a storage function (such as a flipflop or latch). As used herein, a circuit ‘block’ may refer to two or more cells. Both a cell and a circuit block can be referred to as a module or component and are enabled as both physical structures and in simulations. Parameters are specified for selected cells (based on ‘standard cells’) such as size and made accessible in a database for use by EDA products.

During analysis and extraction 926, the circuit function is verified at the layout level, which permits refinement of the layout design. During physical verification 928, the layout design is checked to ensure that manufacturing constraints are correct, such as DRC constraints, electrical constraints, lithographic constraints, and that circuitry function matches the HDL design specification. During resolution enhancement 930, the geometry of the layout is transformed to improve how the circuit design is manufactured.

During tape-out, data is created to be used (after lithographic enhancements are applied if appropriate) for production of lithography masks. During mask data preparation 932, the ‘tape-out’ data is used to produce lithography masks that are used to produce finished integrated circuits.

A storage subsystem of a computer system (such as computer system 1000 of FIG. 10) may be used to store the programs and data structures that are used by some or all of the EDA products described herein, and products used for development of cells for the library and for physical and logical design that use the library.

FIG. 10 illustrates an example machine of a computer system 1000 within which a set of instructions, for causing the machine to perform any one or more of the methodologies discussed herein, may be executed. In alternative implementations, the machine may be connected (e.g., networked) to other machines in a LAN, an intranet, an extranet, and/or the Internet. The machine may operate in the capacity of a server or a client machine in client-server network environment, as a peer machine in a peer-to-peer (or distributed) network environment, or as a server or a client machine in a cloud computing infrastructure or environment.

The machine may be a personal computer (PC), a tablet PC, a set-top box (STB), a Personal Digital Assistant (PDA), a cellular telephone, a web appliance, a server, a network router, a switch or bridge, or any machine capable of executing a set of instructions (sequential or otherwise) that specify actions to be taken by that machine. Further, while a single machine is illustrated, the term “machine” shall also be taken to include any collection of machines that individually or jointly execute a set (or multiple sets) of instructions to perform any one or more of the methodologies discussed herein.

The example computer system 1000 includes a processing device 1002, a main memory 1004 (e.g., read-only memory (ROM), flash memory, dynamic random access memory (DRAM) such as synchronous DRAM (SDRAM), a static memory 1006 (e.g., flash memory, static random access memory (SRAM), etc.), and a data storage device 1018, which communicate with each other via a bus 1030.

Processing device 1002 represents one or more processors such as a microprocessor, a central processing unit, or the like. More particularly, the processing device may be complex instruction set computing (CISC) microprocessor, reduced instruction set computing (RISC) microprocessor, very long instruction word (VLIW) microprocessor, or a processor implementing other instruction sets, or processors implementing a combination of instruction sets. Processing device 1002 may also be one or more special-purpose processing devices such as an application specific integrated circuit (ASIC), a field programmable gate array (FPGA), a digital signal processor (DSP), network processor, or the like. The processing device 1002 may be configured to execute instructions 1026 for performing the operations and steps described herein.

The computer system 1000 may further include a network interface device 1008 to communicate over the network 1020. The computer system 1000 also may include a video display unit 1010 (e.g., a liquid crystal display (LCD) or a cathode ray tube (CRT)), an alphanumeric input device 1012 (e.g., a keyboard), a cursor control device 1014 (e.g., a mouse), a graphics processing unit 1022, a signal generation device 1016 (e.g., a speaker), graphics processing unit 1022, video processing unit 1028, and audio processing unit 1032.

The data storage device 1018 may include a machine-readable storage medium 1024 (also known as a non-transitory computer-readable medium) on which is stored one or more sets of instructions 1026 or software embodying any one or more of the methodologies or functions described herein. The instructions 1026 may also reside, completely or at least partially, within the main memory 1004 and/or within the processing device 1002 during execution thereof by the computer system 1000, the main memory 1004 and the processing device 1002 also constituting machine-readable storage media.

In some implementations, the instructions 1026 include instructions to implement functionality corresponding to the present disclosure. While the machine-readable storage medium 1024 is shown in an example implementation to be a single medium, the term “machine-readable storage medium” should be taken to include a single medium or multiple media (e.g., a centralized or distributed database, and/or associated caches and servers) that store the one or more sets of instructions. The term “machine-readable storage medium” shall also be taken to include any medium that is capable of storing or encoding a set of instructions for execution by the machine and that cause the machine and the processing device 1002 to perform any one or more of the methodologies of the present disclosure. The term “machine-readable storage medium” shall accordingly be taken to include, but not be limited to, solid-state memories, optical media, and magnetic media.

Some portions of the preceding detailed descriptions have been presented in terms of algorithms and symbolic representations of operations on data bits within a computer memory. These algorithmic descriptions and representations are the ways used by those skilled in the data processing arts to most effectively convey the substance of their work to others skilled in the art. An algorithm may be a sequence of operations leading to a desired result. The operations are those requiring physical manipulations of physical quantities. Such quantities may take the form of electronic or magnetic signals capable of being stored, combined, compared, and otherwise manipulated. Such signals may be referred to as bits, values, elements, symbols, characters, terms, numbers, or the like.

It should be borne in mind, however, that all of these and similar terms are to be associated with the appropriate physical quantities and are merely convenient labels applied to these quantities. Unless specifically stated otherwise as apparent from the present disclosure, it is appreciated that throughout the description, certain terms refer to the action and processes of a computer system, or similar electronic computing device, that manipulates and transforms data represented as physical (electronic) quantities within the computer system's registers and memories into other data similarly represented as physical quantities within the computer system memories or registers or other such information storage devices.

The present disclosure also relates to an apparatus for performing the operations herein. This apparatus may be specially constructed for the intended purposes, or it may include a computer selectively activated or reconfigured by a computer program stored in the computer. Such a computer program may be stored in a computer readable storage medium, such as, but not limited to, any type of disk including floppy disks, optical disks, CD-ROMs, and magnetic-optical disks, read-only memories (ROMs), random access memories (RAMs), EPROMS, EEPROMs, magnetic or optical cards, or any type of media suitable for storing electronic instructions, each coupled to a computer system bus.

The algorithms and displays presented herein are not inherently related to any particular computer or other apparatus. Various other systems may be used with programs in accordance with the teachings herein, or it may prove convenient to construct a more specialized apparatus to perform the method. In addition, the present disclosure is not described with reference to any particular programming language. It will be appreciated that a variety of programming languages may be used to implement the teachings of the disclosure as described herein.

The present disclosure may be provided as a computer program product, or software, that may include a machine-readable medium having stored thereon instructions, which may be used to program a computer system (or other electronic devices) to perform a process according to the present disclosure. A machine-readable medium includes any mechanism for storing information in a form readable by a machine (e.g., a computer). For example, a machine-readable (e.g., computer-readable) medium includes a machine (e.g., a computer) readable storage medium such as a read only memory (“ROM”), random access memory (“RAM”), magnetic disk storage media, optical storage media, flash memory devices, etc.

In the foregoing disclosure, implementations of the disclosure have been described with reference to specific example implementations thereof. It will be evident that various modifications may be made thereto without departing from the broader spirit and scope of implementations of the disclosure as set forth in the following claims. Where the disclosure refers to some elements in the singular tense, more than one element can be depicted in the figures and like elements are labeled with like numerals. The disclosure and drawings are, accordingly, to be regarded in an illustrative sense rather than a restrictive sense.

What is claimed is:

1. A system for generating a superconducting electronic circuit design, the system comprising:
a memory; and
a processor communicatively coupled to the memory, the processor configured to:
determine a slope in a voltage pulse at a transmitter for a passive transmission line of a superconducting electronic circuit design;
determine a model for the passive transmission line based on the slope;
simulate the superconducting electronic circuit design using the model; and
make an adjustment to the transmitter based on simulating the superconducting electronic circuit design.

2. The system of claim 1, wherein determining the model for the passive transmission line comprises determining a continuous waveform with a slope that matches the slope in the voltage pulse.

3. The system of claim 2, wherein determining the model is based on a frequency of the continuous waveform.

4. The system of claim 1, wherein determining the model for the passive transmission line comprises determining scattering parameters for the passive transmission line.

5. The system of claim 1, wherein the model expresses how the passive transmission line attenuates at least one of an amplitude, a pulse width, or a shape of the voltage pulse.

6. The system of claim 1, wherein simulating the superconducting electronic circuit design comprises sampling an input signal or output signal of the passive transmission line while varying an input to the model representing a length of the passive transmission line.

7. The system of claim 6, wherein varying the input varies a signal reflection from the passive transmission line.

8. The system of claim 1, wherein simulating the superconducting electronic circuit design comprises sampling an input signal or output signal of the passive transmission line while varying an input to the model representing a periodicity of a voltage pulse to the passive transmission line.

9. A method for generating a superconducting electronic circuit design, the method comprising:
determining a slope in a voltage pulse at a transmitter for a passive transmission line of a superconducting electronic circuit design;
determining a continuous waveform with a slope that matches the slope in the voltage pulse;
determining a frequency range based on a frequency of the continuous waveform; and
determining, by a processor, a model for the passive transmission line based on the frequency range.

10. The method of claim 9, further comprising:
simulating the superconducting electronic circuit design using the model; and
making an adjustment to the transmitter based on simulating the superconducting electronic circuit design.

11. The method of claim 9, wherein determining the slope in the voltage pulse comprises determining a maximum derivative of the voltage pulse and a minimum derivative of the voltage pulse.

12. The method of claim 11, wherein determining the continuous waveform comprises:
determining a first continuous waveform with a maximum derivative that matches the maximum derivative of the voltage pulse and a second continuous waveform with a minimum derivative that matches the minimum derivative of the voltage pulse, wherein the first continuous waveform has a first frequency and the second continuous waveform has a second frequency; and
determining whether the first frequency is greater than the second frequency.

13. The method of claim 9, wherein determining the model for the passive transmission line comprises determining scattering parameters for the passive transmission line.

14. The method of claim 9, wherein the model expresses how the passive transmission line attenuates at least one of an amplitude, pulse width, or shape of the voltage pulse.

15. The method of claim 9, wherein simulating the superconducting electronic circuit design comprises sampling an input signal or output signal of the passive transmission line while varying an input to the model representing a length of the passive transmission line.

16. The method of claim 15, wherein varying the input varies a signal reflection from the passive transmission line.

17. The method of claim 9, wherein simulating the superconducting electronic circuit design comprises sampling an input signal or output signal of the passive transmission line while varying an input to the model representing a periodicity of a voltage pulse to the passive transmission line.

18. A non-transitory computer readable medium storing instructions that, when executed by a processor, cause the processor to:
determine a frequency range of a voltage pulse at a transmitter for a passive transmission line of a superconducting electronic circuit design;
generate a model for the passive transmission line using the frequency range;
sample a reflected signal from the passive transmission line while varying an input to the model representing a length of the passive transmission line; and
adjust the transmitter based on the reflected signal.

19. The medium of claim 18, wherein determining the frequency range comprises fitting a continuous waveform to the voltage pulse.

20. The medium of claim 18, wherein the model comprises scattering parameters for the passive transmission line.
